(19) United States
(12) Patent Application Publication
(10) Pub. No.: US 2007/0231958 A1
(43) Pub. Date: Oct. 4, 2007

(54) Method of manufacturing a composite electronic part, and composite electronic part

(75) Inventor: Isao Akahane, Minowa (JP)

Correspondence Address: HARNESS, DICKEY & PIERCE, P.L.C., P.O. BOX 828, BLOOMFIELD HILLS, MI, 48303, US

(73) Assignee: KOA Corporation

(21) Appl. No.: 11/724,643

(22) Filed: Mar. 15, 2007

(30) Foreign Application Priority Data
Mar. 30, 2006 (JP) 2006-093120

(51) Int. Cl. H01L 21/00

(52) U.S. Cl. 438/106; 438/614; 438/123; 257/676; 29/855

(57) ABSTRACT

A method of manufacturing a composite electronic part includes: a part arrangement step of arranging a film circuit element and a chip-like electronic part on one substrate surface of a ceramic substrate; a protective layer disposition step of disposing a protective layer that protects the film circuit element and the chip-like electronic part on the one substrate surface of the ceramic substrate, and flattening an upper surface of the protective layer; and a conductive material arrangement step of, after both of the steps, arranging a plurality of conductive projections that become terminals of the film circuit element and the chip-like electronic part on the other surface of the ceramic substrate in a state where the upper surface of the protective layer abuts on a horizontal plane.

### CROSS-REFERENCES TO RELATED APPLICATION

This application claims priority to Japanese Application No. 2006-093120 filed Mar. 30, 2006, the entire disclosures of which is hereby incorporated by reference.

### BACKGROUND OF THE INVENTION

1. Field of the Invention

The present invention relates to a method of manufacturing a composite electronic part, and the composite electronic part.

2. Description of the Related Art

Heretofore, there has been known a ball grid array type composite electronic part, in which circuit elements are mounted on a surface of a ceramic substrate made of alumina or the like, and external terminals are formed of conductive balls made of solders and the like. Further, a technique of flattening an upper surface of a protective film of the electronic part has also been known.

In the ball grid array type electronic part, usually, after the circuit elements are mounted on the surface of the ceramic substrate, the conductive balls and the like are mounted and fixed onto the surface of the ceramic substrate, thereby forming conductive projections. Before the conductive balls and the like are mounted, it is necessary to uniformly dispose a fixing member such as a solder paste (cream solder) on the surface of the ceramic substrate. However, when a height difference between the mounted circuit elements is large, it becomes difficult to stably handle the ceramic substrate. Therefore, it sometimes becomes difficult to uniformly dispose the solder paste or the like on the surface of the ceramic substrate.

In order to stably handle the ceramic substrate, it is necessary to eliminate the height difference between the mounted circuit elements. Accordingly, heretofore, there has been known a technique of substantially flattening an upper surface of an electronic part, in which a first protective film is formed on the entirety of two circuit elements that have the height difference therebetween and have thick films formed on both thereof, and then a second protective film is separately formed on an upper surface of the circuit element with a smaller height by a screen printing method or the like. However, in a composite electronic part including film circuit elements and chip-like electronic parts, the height difference between the circuit elements is too large. Therefore, with this composite electronic part, it is practically impossible to separately implement screen printing for the lower circuit element.

Further, heretofore, there has been known a technique of flattening an upper surface of a fluid resin, in which a plurality of IC chips different in height are allowed to adhere onto a board, the fluid resin is disposed among the IC chips and on upper surfaces of the IC chips by spin coating, and the fluid resin is cured while mounting a board member on upper surfaces of the IC chips. However, it is also difficult to apply this technique to the composite electronic part having a structure in which the film circuit elements and the chip-like electronic parts are mounted on the surface of the ceramic substrate. Specifically, the height difference between the film circuit elements and the chip-like electronic parts is too large. Therefore, even if the fluid resin with viscosity that allows the spin coating is once spread up to the upper surfaces of both of the circuit elements, the resin runs off when work of curing the fluid resin is ended. As a result, the upper surfaces of the circuit elements are not flattened.

### SUMMARY OF THE INVENTION

It is an object of the present invention to provide a method of manufacturing a composite electronic part, which is capable of forming conductive projections while stably handling a ceramic substrate even if a height difference between formed circuit elements is large, and to provide the composite electronic part, which is capable of forming conductive projections while stably handling a ceramic substrate even if a height difference between formed circuit elements is large.

In order to achieve the above-mentioned object, according to the present invention, there is provided a method of manufacturing a composite electronic part, including the steps of: arranging a film circuit element and a chip-like electronic part on one surface of a ceramic substrate; disposing a protective layer for protecting the film circuit element and the chip-like electronic part on the one surface of the ceramic substrate, and flattening an upper surface of the protective layer; and after both of the part arrangement step and the protective layer disposition step, arranging a plurality of conductive projections that become terminals of the film circuit element and the chip-like electronic part on another surface of the ceramic substrate in a state where the upper surface of the protective layer abuts on a horizontal plane.

According to the present invention, the upper surface of the protective layer is substantially flat even if the height difference between the formed circuit elements is large. Therefore, it is possible to realize stable handling of the ceramic substrate and the composite electronic part, and the like while taking the upper surface of the protective layer as a reference surface. Further, in a case of forming the conductive projections, the conductive projections can be fixed to the ceramic substrate while making the upper surface of the protective layer abut on a horizontal plane. Therefore, the other surface of the ceramic substrate, on which the conductive projections are formed, becomes a substantially horizontal plane. Hence, it becomes easy to perform work of forming the conductive projections.

Further, in order to achieve the above-mentioned object, according to the present invention, there is provided another method of manufacturing a composite electronic part, including the steps of: arranging a film circuit element and a chip-like electronic part on one surface of a large-scale ceramic substrate that becomes a large number of unit ceramic substrates by being divided; disposing a protective layer for protecting the film circuit element and the chip-like electronic part on the one surface of the large-scale ceramic substrate, and flattening an upper surface of the protective layer; after both of the part arrangement step and the protective layer disposition step, arranging a plurality of conductive projections that become terminals of the film circuit element and the chip-like electronic part on another surface of the large-scale ceramic substrate in a state where the upper surface of the protective layer abuts on a horizontal plane; and dividing the large-scale ceramic substrate together with the protective layer.

According to the present invention, the upper surface of the protective layer is substantially flat even if the height difference between the formed circuit elements is large. Hence, it is possible to realize stable handling of the large-scale ceramic substrate or the unit ceramic substrate and the composite electronic part, and the like while taking the upper surface of the protective layer as the reference surface. Further, in the case of forming the conductive projections, the conductive projections can be fixed to the ceramic substrate while making the upper surface of the protective layer abut on the horizontal plane. Therefore, the other surface of the ceramic substrate, on which the conductive projections are formed, becomes the substantially horizontal plane. Hence, it becomes easy to perform the work of forming the conductive projections. Further, the circuit elements can be formed for each of the unit ceramic substrates in a state of the large-scale ceramic substrate. Accordingly, mass productivity of the composite electronic part is enhanced.

Further, in order to achieve the above-mentioned object, according to the present invention, there is provided a composite electronic part, including: a ceramic substrate; a film-circuit element; a chip-like electronic part; a protective layer for protecting the film circuit element and the chip-like electronic part, the protective layer being disposed on one surface of the ceramic substrate; and a plurality of conductive projections that become terminals of the film circuit element and the chip-like electronic part, the conductive projections being arranged on another surface of the ceramic substrate, in which a difference between a maximum value and a minimum value of distances from an upper surface of the protective layer to the another surface of the ceramic substrate is 2 μm or more to 100 μm or less.

According to the present invention, the upper surface of the protective layer is substantially flat even if the height difference between the formed circuit elements is large. Further, the upper surface of the protective layer and the other surface of the ceramic substrate are substantially parallel to each other. Therefore, it is possible to realize stable handling of the ceramic substrate and the composite electronic part, and the like while taking the upper surface of the protective layer as a reference surface. In particular, when, in the case of forming the conductive projections, the conductive projections can be fixed to the ceramic substrate while making the upper surface of the protective layer abut on a horizontal plane, the other surface of the ceramic substrate, on which the conductive projections are formed, becomes a substantially horizontal plane. Hence, it becomes easy to perform work of forming the conductive projections.

### BRIEF DESCRIPTION OF THE DRAWINGS

In the accompanying drawings:

FIG. 1 are views showing a composite electronic part according to an embodiment of the present invention, in which FIG. 1A is a longitudinal cross-sectional view, and FIG. 1B is a plan view of one surface of a substrate, with a protective layer and a first solder being omitted;

FIG. 2 is a plan view showing the composite electronic part according to the embodiment of the present invention when viewed from a side of the other surface of the substrate;

FIG. 3 is a plan view of a large-scale ceramic substrate according to the embodiment of the present invention when viewed from a side of one surface of the substrate;

FIG. 4 are views for explaining a method of manufacturing a composite electronic part according to the embodiment of the present invention, sequentially showing a product in respective manufacturing steps;

FIG. 5 are views for explaining the method of manufacturing a composite electronic part according to the embodiment of the present invention, sequentially showing the product in respective manufacturing steps that follow the manufacturing steps shown in FIG. 4; and

FIG. 6 are views showing a modification example of the method of manufacturing a composite electronic part according to the embodiment of the present invention, showing a modification example of a resin embedding step.

### DESCRIPTION OF THE PREFERRED EMBODIMENTS

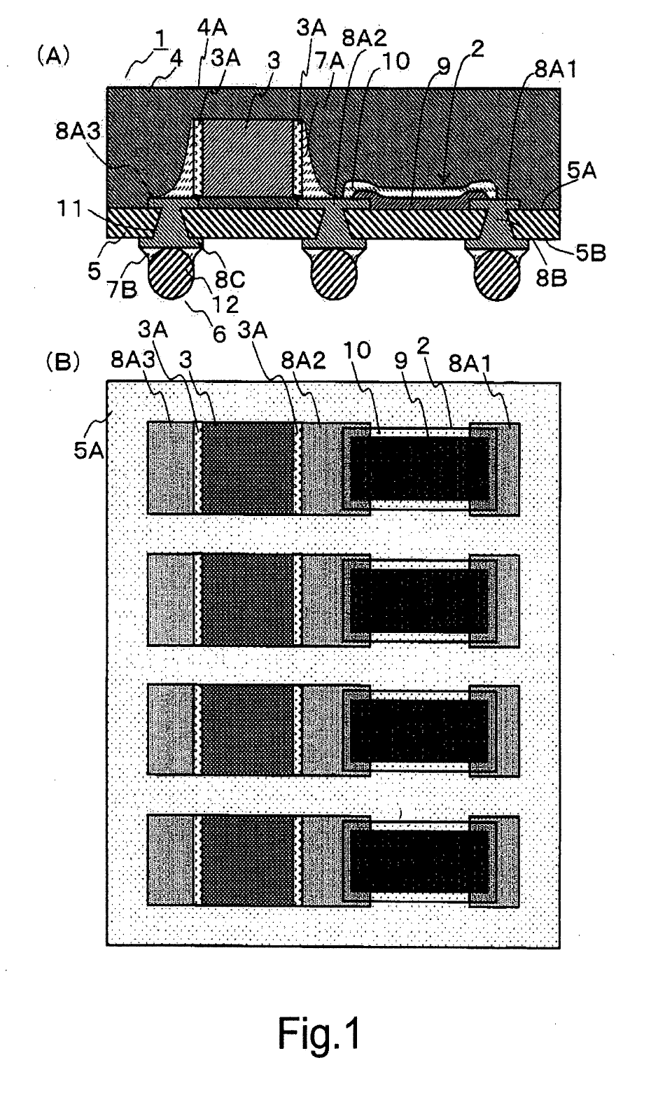

FIG. 1A is an example of a longitudinal cross-sectional view of a composite electronic part 1 according to an embodiment of the present invention. On one surface 5A of a ceramic substrate 5 (hereinafter, abbreviated as “one substrate surface 5A”), resistor elements 2 that become film circuit elements and chip capacitors 3 that become chip-like electronic parts are arranged. Further, on the one substrate surface 5A, a protective layer 4 that protects the resistor elements 2 and the chip capacitors 3 is disposed. On the other surface 5B of the ceramic substrate 5 (hereinafter, abbreviated as “other substrate surface 5B”), a plurality of conductive projections 6 that become terminals of the resistor elements 2 and the chip capacitors 3 are arranged. A difference between the maximum value and the minimum value of distances from an upper surface (flat surface 4A) of the protective layer 4, which is exposed to a side opposite to a side that abuts on the one substrate surface 5A, to the other substrate surface 5B is 100 μm or less. Note that, in this embodiment, the resistor elements 2 and the chip capacitors 3 correspond to circuit elements.

Each of the resistor elements 2 includes a resistor element electrode 8A1 and a common electrode 8A2, which are formed on the one substrate surface 5A, and a resistor 9 formed so as to contact both of the electrodes 8A1 and 8A2. Further, the resistor 9 is covered with a glass film 10. The chip capacitor 3 includes a pair of terminal electrodes 3A. The chip capacitor 3 is mounted on both of a capacitor electrode 8A3 and the common electrode 8A2, which are formed on the one substrate surface 5A. Specifically, the chip capacitor 3 is disposed so as to build a bridge between the capacitor electrode 8A3 and the common electrode 8A2. One of the pair of terminal electrodes 3A is electrically connected to the capacitor electrode 8A3 by one piece of first solder 7A, and the other terminal electrode 3A is electrically connected to the common electrode 8A2 by the other piece of the first solder 7A. Further, the pair of terminal electrodes 3A are fixed to the capacitor electrode 8A3 and the common electrode 8A2 by the first solder 7A. Further, on the other substrate surface 5B, circular external electrodes 8C are formed.

FIG. 1B is a plan view of the one substrate surface 5A side of the composite electronic part 1 shown in FIG. 1A. In FIG. 1B, the first solders 7A that fix the protective layer 4 and the chip capacitors 3 are omitted. As shown in FIG. 1B, on the one substrate surface 5A, four composite elements in which the resistor elements 2 and the chip capacitors 3 are connected to each other are mounted. Those four composite elements are arranged at equal intervals.

In the ceramic substrate 5, a plurality of holes 11 that extend from the one substrate surface 5A to the other substrate surface 5B are formed. An opening area of each hole 11 on the one substrate surface 5A side is smaller than an opening area of each hole 11 on the other substrate surface 5B side. Specifically, each hole 11 forms a space of a conical trapezoidal shape with a diameter becoming smaller toward the one substrate surface 5A. The resistor elements 2, the chip capacitors 3, and the conductive projections 6 are electrically connected to one another through connection electrodes 8B including conductive substances filling the holes 11. Specifically, the resistor element electrodes 8A1, the common electrodes 8A2, and the capacitor electrodes 8A3 are electrically connected to the external electrodes 8C through the connection electrodes 8B.

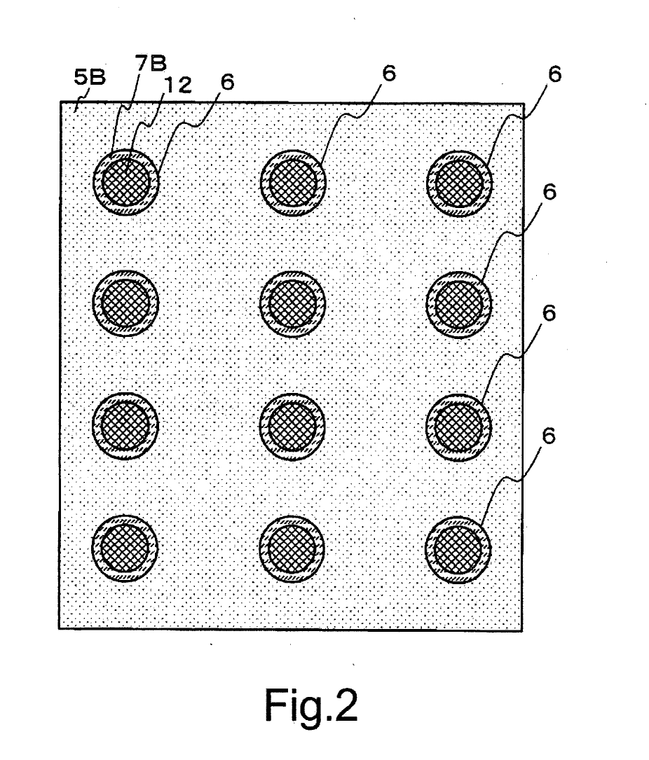

To each surface of the external electrode 8C, a spherical conductive ball 12 is fixed by a second solder 7B. An outer shape of the second solder 7B becomes circular. In this embodiment, the external electrode 8C, the conductive ball 12, and the second solder 7B are integrated together, thereby constructing the conductive projection 6. FIG. 2 is a plan view of the other substrate surface 5B side of the composite electronic part 1 shown in FIG. 1A. In this embodiment, each of the four composite elements mounted on the one substrate surface 5A is connected to three conductive projections 6. Therefore, as shown in FIG. 2, twelve conductive projections 6 in total project from the other substrate surface 5B.

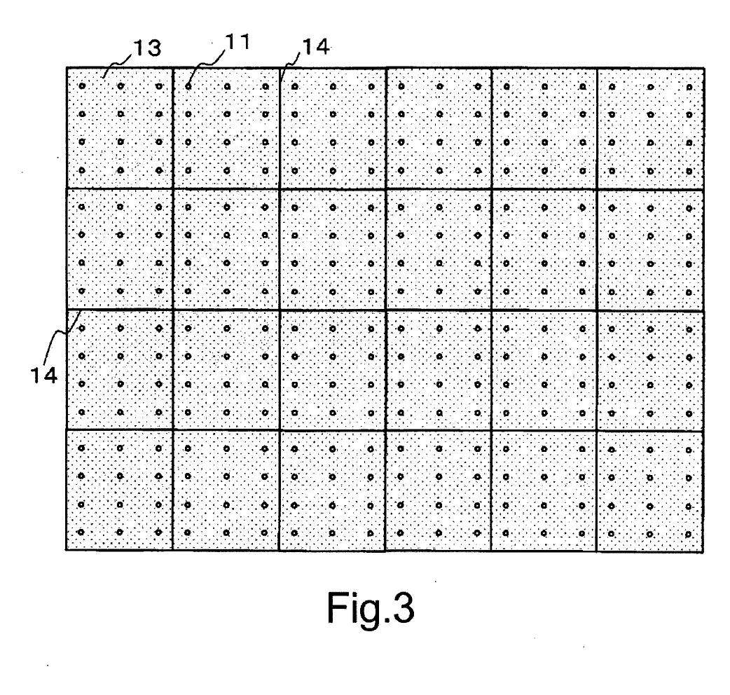

Next, a description will be made of an example of a method of manufacturing the composite electronic part 1 according to this embodiment of the present invention while referring to FIGS. 3 to 5.

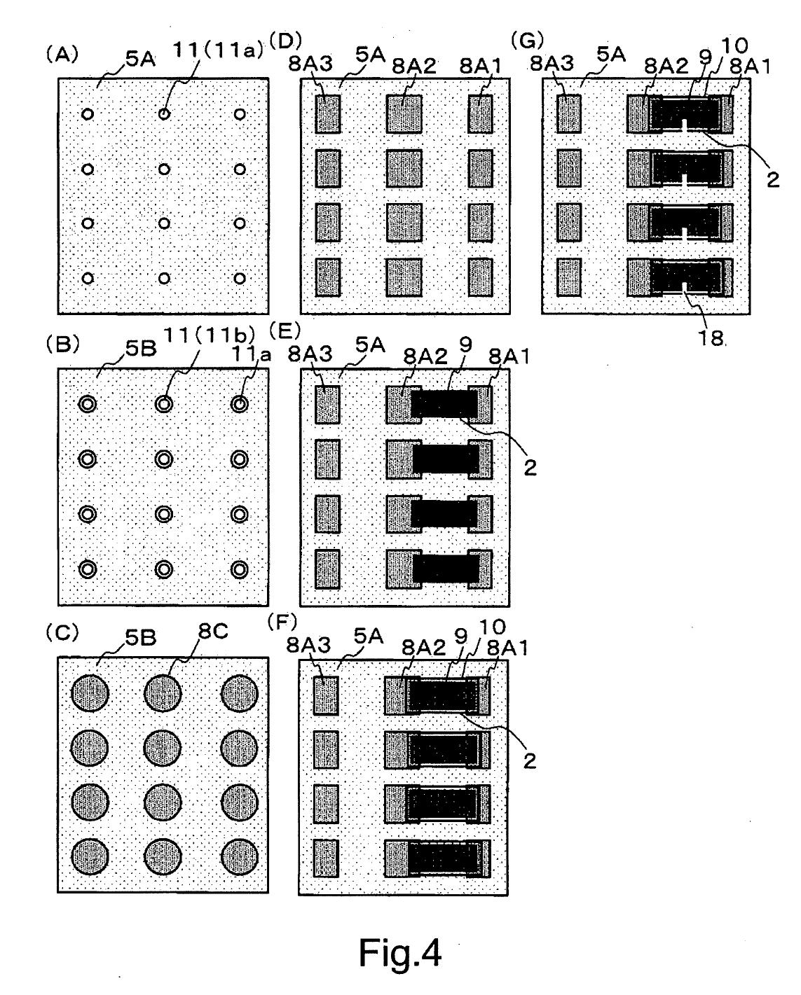

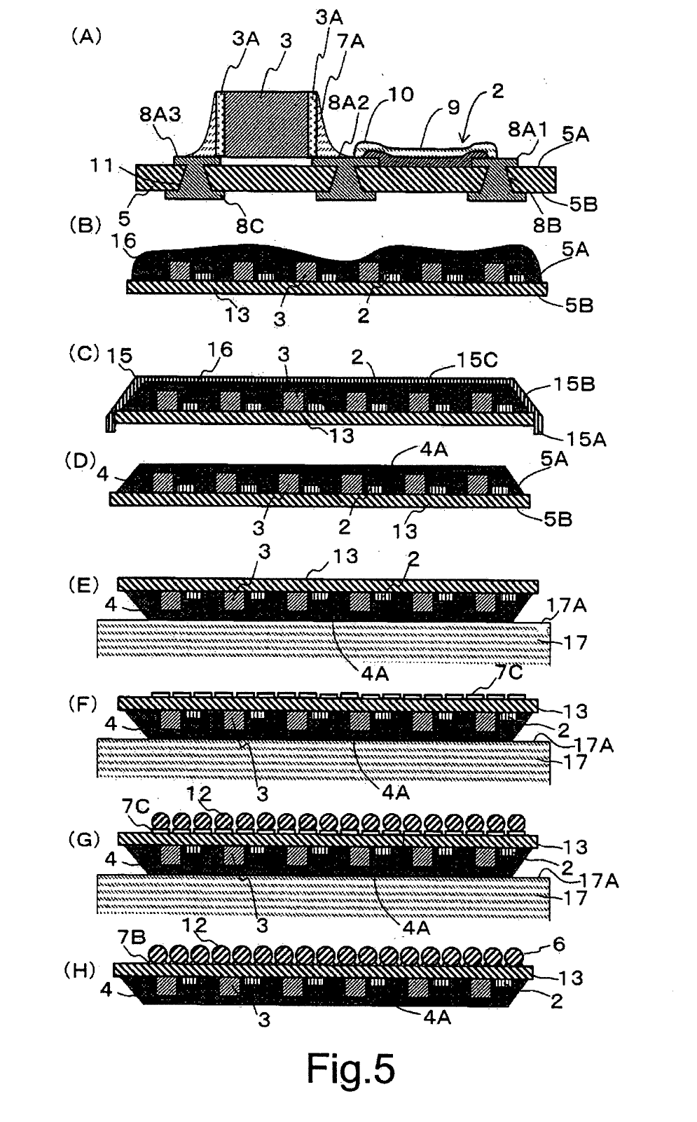

FIG. 3 shows a large-scale ceramic substrate 13 made of alumina. On a surface of the large-scale ceramic substrate 13, linear dividing portions 14 that intersect one another perpendicularly are formed. Note that, though FIG. 3 illustrates the linear dividing portions 14, the linear dividing portions 14 are actually invisible to a naked eye. Further, though steps shown in FIGS. 4 and 5 are performed for the large-scale ceramic substrate 13, FIGS. 4 and 5A each only illustrate the ceramic substrate 5 obtained by the division by the linear dividing portions 14 (hereinafter, referred to as “unit ceramic substrate 5”) for convenience of explanation. Specifically, though FIGS. 4A to 4G and 5A each illustrate the unit ceramic substrate 5, actually, in those steps, the large-scale ceramic substrate 13 is not divided by the linear dividing portions 14, and the large-scale ceramic substrate 3 is subjected to processing as it is. Further, hereinafter, substrate surfaces of the large-scale ceramic substrate 13, which correspond to the one substrate surface 5A and other substrate surface 5B of the unit ceramic substrate 5, respectively, will be represented as “one substrate surface 5A” and “other substrate surface 5B” in a similar way to the above.

FIG. 4A shows the one substrate surface 5A of the unit ceramic substrate 5. FIG. 4B shows the other substrate surface 5B of the unit ceramic substrate 5. As described above, an opening 11a of each hole 11, which opens on the one substrate surface 5A, is smaller than an opening 11b of each hole 11, which opens on the other substrate surface 5B. FIG. 4C shows a state where a metal-glaze conductive paste containing Ag (silver) as a main material is arranged at positions of the openings 11b of the holes 11 by a screen printing method. In a case of the screen printing, the entire or major spaces of the holes 11 are filled with the conductive paste. Since the openings 11b are larger than the openings 11a, work of filling the holes can be smoothly performed. After the step of screen printing, the metal-glaze conductive paste is solidified by being fired together with the large-scale ceramic substrate 13. By the solidification, the external electrodes 8C and the entirety or majority of the connection electrodes 8B are formed. The external electrodes 8C and the entirety or majority of the connection electrodes 8B are formed, thereby ending a part of a part arrangement step.

After that, as shown in FIG. 4D, a metal-glaze conductive paste containing an Ag—Pd (silver-palladium) alloy as a main material is disposed at positions of the holes 11 on the one substrate surface 5A by the screen printing method. Here, when the connection electrodes 8B are not entirely formed (that is, when the holes 11 are not filled with the connection electrodes 8B) in the previous step, the rest of the holes 11 are filled with the metal-glaze conductive paste by such screen printing at this time. Specifically, the entire spaces of the holes 11 can be filled with the conductive substances by the screen printing at this time. After the step of screen printing, the conductive substances are solidified by being fired together with the large-scale ceramic substrate 13. By the solidification, the resistor element electrodes 8A1, the common electrodes 8A2, and the capacitor electrodes 8A3 are formed. At this time, when the connection electrodes 8B are not entirely formed in the previous step, the connection electrodes 8B are entirely formed by the solidification. The resistor element electrodes 8A1, the common electrodes 8A2, the capacitor electrodes 8A3, and the connection electrodes 8B are entirely formed, and a part of the part arrangement step is thereby ended.

Note that, by the solidification in this step, the connection electrodes 8B are integrated with each of the electrodes 8A1, 8A2 and 8A3. Specifically, boundaries between the connection electrodes 8B and each of the electrodes 8A1, 8A2 and 8A3 do not clearly appear. Specifically, boundary portions between the connection electrodes 8B and each of the electrodes 8A1, 8A2 and 8A3 are fused by mutual erosion of those, thereby making those into one conductive substance. Therefore, the resistor element electrodes 8A1, the common electrodes 8A2, and the capacitor electrodes 8A3 are brought into electrical conduction with the external electrodes 8C via the connection electrodes 8B.

After that, as shown in FIG. 4E, a metal-glaze resistor paste containing ruthenium oxide as a main material is disposed by the screen printing method so as to come into contact with both of the resistor element electrodes 8A1 and the common electrodes 8A2. After the step of screen printing, the metal-glaze resistor paste is fired together with the large-scale ceramic substrate 13. By the firing, the resistors 9 that are solidified are obtained. Further, in the step, the resistor elements 2 composed of the resistor element electrodes 8A1, the common electrodes 8A2, and the resistors 9 that connect to both of those are obtained. The resistor elements 2 are formed, thereby ending a part of the part arrangement step.

FIG. 4F shows a state where the glass films 10 that cover the resistors 9 are formed. In a case of forming the glass films 10, a glass paste is disposed on the one substrate surface 5A of the large-scale ceramic substrate 13 by the screen printing method. Specifically, the glass paste is disposed at positions where the previously formed resistors 9 are covered therewith. After the step of screen printing, the glass paste is fired together with the large-scale ceramic substrate 13, and the glass films 10 that are solidified are obtained. FIG. 4G shows the following state where trimming grooves 18 are formed in the resistors 9 by laser radiation in order to adjust a resistance value of the resistor elements 2. The previously formed glass films 10 serves to prevent excessive breakage of the resistors 9 due to the laser radiation.

After that, a cream solder (not shown) is disposed on the surfaces of the common electrodes 8A2 and the capacitor electrodes 8A3 by the screen printing method. Then, as shown in FIG. 5A, each of the chip capacitors 3 is mounted such that the cream solder and the terminal electrode 3A of the chip capacitor 3 come into contact with each other. The cream solder serves to temporarily fix (fix with weak force) the chip capacitor 3. After that, after a so-called reflow step, the cream solder is molten/solidified, and becomes the first solder 7A. The first solder 7A electrically connects the terminal electrode 3A of each chip capacitor 3 to the common electrode 8A2 and the capacitor electrode 8A3, and fix the chip capacitor 3. The chip capacitor 3 is formed to be taller by approximately 0.7 mm than the highest portion of the glass film 10 in the height direction. The chip capacitor 3 is fixed, thereby ending the entirety of the part arrangement step.

After that, as shown in FIG. 5B, a resin paste 16 is supplied by a dispenser or the like to the one substrate surface 5A of the large-scale ceramic substrate 13 for which the entirety of the part arrangement step is ended. In this case, a retaining member (not shown) that prevents an outflow of the resin paste 16 is disposed on the one substrate surface 5A according to needs. Then, a quadrangular dish-like frame 15 shown in FIG. 5C is prepared. A frame inner surface of the frame 15 is coated with a tetrafluoroethylene resin. Further, on the frame 15, a tapered portion 15B is formed so that all four side portions thereof can be widened toward an opening 15A thereof. Further, a bottom surface of the frame 15 becomes a flat portion 15C. The opening 15A of the frame 15 is fitted to end surfaces of the large-scale ceramic substrate 13 to which the resin paste 16 has been supplied.

After that, an inside of the frame 15 is deaerated according to needs. This is for the purpose of avoiding damage, which may be caused by the presence of the air in the inside of the frame 15, to flatness of the upper surface of the protective layer 4 to be formed later. As described above, the resin paste 16 fills, without leaving any gap, the inside of the frame 15, including portions between the chip capacitors 3 and the resistor elements 2. By the filling with the resin, the resin paste 16 also enters the previously formed trimming grooves 18. The resin paste 16 that has entered the trimming grooves 18 also protects the trimming grooves 18. Further, the resin paste 16 that is extra and overflows from the inside of the frame 15 is removed. Note that, in FIGS. 5B to 5H, illustration of the respective electrodes and the like which are formed on the large-scale ceramic substrate 13 is omitted.

After that, the resin paste 16 is heated, as shown in FIG. 5C, and the resin paste 16 is cured. When the resin paste 16 is heated, the flat portion 15C is pressurized toward the large-scale ceramic substrate 13 according to needs. After that, as shown in FIG. 5D, the large-scale ceramic substrate 13 is taken out of the frame 15. Then, the resin paste 16 becomes the protective layer 4. The protective layer 4 is adhered onto the large-scale ceramic substrate 13. Specifically, the frame inner surface of the frame 15 is coated with the tetrafluoroethylene resin, and the tapered portion 15B is formed on the frame 15, accordingly, the protective layer 4 can be easily peeled off from the frame 15. Hence, the protective layer 4 is adhered onto the large-scale ceramic substrate 13. Then, on the large-scale ceramic substrate 13 taken out of the frame 15, flatness of the flat portion 15C of the frame 15 is transferred to the upper surface of the protective layer 4, which is formed (exposed) on an opposite side with a side that abuts on the one substrate surface 5A. The upper surface of the protective layer 4 becomes the flat surface 4A. As described above, even in the case of using the resin paste 16 with low viscosity, the upper surface of the protective layer 4 can be flattened irrespective of the height difference between the resistor elements 2 and the chip capacitors 3. The flatness of the flat surface 4A is to an extent where the difference between the maximum value and the minimum value of the distance from the upper surface (flat surface 4A) of the protective layer 4 to the other substrate surface 5B becomes 100 μm or less. Since both of the flat surface 4A and the other substrate surface 5B are flat, the large-scale ceramic substrate 13 can be stably handled even if the height difference between the formed circuit elements (resistor elements 2 and chip capacitors 3) is large. The protective layer 4 having the flat surface 4A is formed, thereby ending a protective layer deposition step. Note that the formation of the flat surface 4A also allows stable handling of the unit ceramic substrates 5 obtained by the partitioning.

After that, as shown in FIG. 5E, a fixing jig 17 of which upper surface is flat is prepared. Then, in a state where a fixing jig flat portion 17A, which become horizontal surfaces, and the flat surface 4A of the protective layer 4 abut on each other, the entirety of the large-scale ceramic substrate 13 is fixed to the fixing jig 17. After that, as shown in FIG. 5F, a cream solder 7C is disposed on the external electrodes 8C formed on the other substrate surface 5B by the screen printing method. Since the flat surface 4A is flat, disposition amounts of the cream solder 7C onto the respective spots of the other substrate surface 5B can be made substantially uniform at the time of the screen printing by simple means for making the flat surface 4A abut on the fixing jig flat portion 17A that is flat and fixing the flat surface 4A thereto. As a matter of course, even if the upper surface of the protective layer 4 is not flat, depending on a shape of the upper surface of the fixing jig 17, the disposition amounts of the cream solder 7C onto the respective spots of the other substrate surface 5B can be made substantially uniform at the time of the screen printing. However, it is difficult to form the shape of the upper surface of the fixing jig 17, which is as described above. Practically, the large-scale ceramic substrate 13 cannot be stably handled.

After that, as shown in FIG. 5G, the conductive balls 12 (copper-core balls) formed by giving tin plating to surfaces of copper balls are mounted on the cream solder 7C. The cream solder 7C plays a role to temporarily fix (fix with weak force) the conductive balls 12. After that, after the so-called reflow step, as shown in FIG. 5H, the cream solder 7C is molten/solidified to be the second solder 7B. The second solder 7B fixes the conductive balls 12 to the external electrodes 8C. In this way, the conductive projections 6 are obtained. As shown in FIG. 2, the conductive projections 6 are arrayed at equal intervals vertically and horizontally. The conductive projections 6 are formed, thereby ending the conductive material arrangement step.

Here, if the difference between the maximum value and the minimum value of the distance from the upper surface of the protective layer 4 to the other substrate surface 5B of the large-scale ceramic substrate 13 exceeds 100 μm, and the flatness of the upper surface of the protective layer 4 is not high, then unevenness occurs in the disposition amount of the cream solder 7C owing to an inclination of a printing surface (other substrate surface 5B). As a result, in a portion where the disposition amount of the cream solder 7C is small, adhesion strength of the conductive protrusions 6 to the other substrate surface 5B is weak, which is not preferable. Further, in the portion where the disposition amount of the cream solder 7C is small, a correction effect for disposing positions of the conductive balls 12 due to surface tension of the solder while being molten, cannot be sometimes expected, which is not preferable. Further, when the other substrate surface 5B is inclined, the reflow step is performed in a state where the gravity acts in a rolling direction of the conductive balls 12, that is, in a direction of the inclination. Therefore, there is a risk of accuracy of mounting positions of the conductive balls 12 being decreased. The composite electronic part 1 according to this embodiment can resolve those disadvantageous points.

After that, dicing is performed along the linear dividing portions 14 shown in FIG. 3, and the large-scale ceramic substrate 13 is divided into the individual composite electronic parts 1. When the division step ends, each individual composite electronic part 1 can be obtained.

In each composite electronic part 1, the difference between the maximum value and the minimum value of the distance from the upper surface (flat surface 4A) of the protective layer 4 to the other substrate surface 5B is 100 μm or less. Further, in the composite electronic part 1, a difference between the maximum distance and the minimum distance from vertexes of the plurality of conductive projections 6 to the flat surface 4A is 5 μm or more to 100 μm or less. The reason why the distances from the vertexes of the plurality of conductive projections 6 to the flat surface 4A can be uniform is that the flat surface 4A is flat. Specifically, the reason is that the flat surface 4A is flat, and that the disposition amounts of the cream solder 7C as a constituent element of the conductive projections 6 onto the respective spots of the other substrate surface 5B can be made substantially uniform. Further, as a collateral reason, there can be mentioned that the copper-core balls which are the conductive balls 12 have property not to be excessively molten at the time of the reflow step. As described above, when the difference between the maximum distance and the minimum distance from the vertexes of the plurality of conductive projections 6 to the flat surface 4A is 5 μm or more to 100 μm or less, heights of the conductive projections 6 from the other substrate surface 5B become substantially uniform. Therefore, an occurrence rate of noncontact spots where a land of the packaged circuit board and the conductive projections 6 do not come into contact with each other in the case of mounting the composite electronic part 1 on a packaged circuit board decreases. Note that the reason why the difference between the maximum distance and the minimum distance from the vertexes of the plurality of conductive projections 6 to the flat surface 4A is set to 5 μm or more is that there are variations in diameter of the conductive balls 12 which are the cooper-core balls. Specifically, since there are variations in diameter of the conductive balls 12, it is difficult to reduce a value of the difference to less than 5 μm. Hence, to increase work efficiency, the value of the difference is set to 5 μm or more. Further, it is preferable to set the value of the difference to 10 μm or more in terms of the work efficiency.

Note that, on the one substrate surface 5A of the ceramic substrate 5, the plurality of resistor elements 2 and chip capacitors 3 are arranged relatively complicatedly. Therefore, in this embodiment in which the opening area of each hole 11 on the one substrate surface 5A is made smaller than the opening area of each hole 11 on the other substrate surface 5B, a plenty of effective area (insulated portion) of the one substrate surface 5A can be ensured. Meanwhile, on the other substrate surface 5B of the ceramic substrate 5, the conductive projections 6 having a relatively large allowance in design are arranged. Therefore, even if the opening area of each hole 11 on the other substrate surface 5B is large and an effective area of the other substrate surface 5B is small, the conductive projections 6 can be arranged on the other substrate surface 5B without any trouble.

The description has been made above of the composite electronic part 1 and the manufacturing method thereof in this embodiment. However, it is possible to implement various modifications without departing from the gist of the present invention. For example, in the above embodiment, the resistor element electrodes 8A1, the common electrodes 8A2, and the capacitor electrodes 8A3, the external electrodes 8C, and the resistors 9 are formed of thick films formed by the screen printing method. However, the entirety or a part of those may be formed of thin films by a sputtering method or the like. Further, the step of forming the external electrodes 8C, which is shown in FIG. 4C, may be performed after the step of forming the resistor element electrodes 8A1, the common electrodes 8A2, and the capacitor electrodes 8A3, which is shown in FIG. 4D. However, when the large-scale ceramic substrate 13 is mounted on a metal-made conveyor belt or the like in the case of the firing, metal rust on a surface of the conveyor belt is sometimes adheres onto the resistor element electrodes 8A1, the common electrodes 8A2, and the capacitor electrodes 8A3. Therefore, in some cases, a contact state between the resistors 9 to be formed later, and the resistor element electrodes 8A1 and the common electrodes 8A2 becomes unstable. Hence, as in this embodiment, it is preferable that the step of forming the external electrodes 8C be performed before the step of forming the resistor element electrodes 8A1, the common electrodes 8A2, and the capacitor electrodes 8A3. Further, the external electrodes 8C may be composed of the one obtained by firing the metal-glaze paste (for example, Ag—Pd alloy) as a migration restrictive material. In this case, even if a distance between the adjacent external electrodes 8C is relatively small, a short circuit between the external electrodes 8C due to the migration can be restricted. Further, the part arrangement step, the protective layer disposition step, and the conductive material arrangement step may be performed for the unit ceramic substrate 5 from an initial stage without using the large-scale ceramic substrate 13. In this case, the division step can be omitted. Further, in such a case where the trimming grooves 18 are not formed, the glass films 10 do not have to be formed.

Further, in the composite electronic part 1 according to this embodiment, the connection electrodes 8B are formed in the part arrangement step. However, with regard to a forming period of the connection electrodes 8B, the connection electrodes 8B may be formed in advance at a previous stage to the part arrangement step. Further, the connection electrodes 8B may be formed at a stage of the conductive material arrangement step, for example, at the same time when the constituent elements (such as conductive balls 12) of the conductive projections 6 are formed. Further, the forming period of the connection electrodes 8B may be divided into two stages.

Further, in the composite electronic part 1 according to this embodiment, the connection electrodes 8B are formed by filling the holes 11 with the conductive substances. However, the connection electrodes 8B may be formed by adhering the conductive substances onto inner wall surfaces of the holes 11. Further, the first solder 7A and the second solder 7B according to this embodiment may be a so-called lead-free solder such as a Pb—Sn alloy, Sn—Cu alloy, and a simplex substance of Sn (tin). Further, the first solder 7A and the second solder 7B may be replaced, for example, by a conductive adhesive such as an epoxy adhesive containing conductive powder of Ag or the like. Specifically, the first solder 7A and the second solder 7B may be replaced by other materials having a necessary function such as conductivity. Further, the material of the ceramic substrate 5 is not limited to alumina, and may be a material having good thermal conductivity, such as aluminum nitride.

Further, the material of the protective layer 4 is not limited to the epoxy resin, and may be acrylic resin, liquid crystal polymers having good heat radiation property, thermoplastic resins, glasses, or the like. When the material of the protective layer 4 is thermosetting resin such as the epoxy resin, it is preferable to detach the large-scale ceramic substrate 13 added with the protective layer 4 from the frame 15 after heating up the protective layer 4 at a temperature exceeding a glass transition point thereof. In this way, the protective layer 4 can be smoothly peeled off from the frame 15. Further, depending on the material of the protective layer 4 and the forming method thereof, it sometimes becomes easy to peel off the protective layer 4 from the frame 15 even if the tetrafluoroethylene resin is not coated on the frame inner surface of the frame 15, or even if the tapered portion 15B is not formed on the frame 15. For example, the case occurs when a material having good peeling property, such as the tetrafluoroethylene resin, is used as the material of the protective layer 4. Further, in the protective layer 4 according to this embodiment, the resin paste 16 fills, without leaving any gap, the inside of the frame 15, including portions between the chip capacitors 3 and the resistor elements 2. However, some gaps (hollows) may be present in the protective layer 4 as long as the flatness of the upper surface of the protective layer 4 is not damaged. Further, it is important to maintain the other substrate surface 5B at the horizontal state. Hence, the flat surface 4A may be made as a flat surface inclined with respect to the one substrate surface 5A as long as the horizontal state of the other substrate surface 5B is maintained.

Further, the conductive balls 12 may be lead-containing or lead-free solder balls, or may be conductive resin-core balls. However, in the case of coating, with the protective layer 4, the resistor elements 2 covered with the glass films 10 as in this embodiment, it is difficult to dissipate Joule heat generated by the resistor elements 2. Therefore, as the conductive balls 12, it is preferable to use the copper-core balls having good thermal conductivity and higher hardness than the solder. When the conductive balls 12 are the copper-core balls, the Joule heat generated by the resistor elements 2 can be dissipated efficiently. Further, in this case, deformation of the conductive balls 12 can be prevented. Further, the copper-core balls have the property not to be excessively molten when the composite electronic part 1 is mounted on the packaged circuit board. Therefore, as compared to the case where the conductive balls 12 are the solder balls or the like, in the case where the conductive balls 12 are the copper-core balls, the occurrence rate of the noncontact spots where the conductive balls 12 and the land of the packaged circuit board do not come into contact with each other decreases. Note that the surfaces of the copper-core balls may be coated with a low-melting-point alloy (for example, Pb—Sn alloy or Cu—Sn alloy (solder)) or the like, which is other than tin.

Further, in the composite electronic part 1 according to this embodiment, the film-like resistor elements 2 and the chip capacitors 3 are connected to each other. However, in the composite electronic part, capacitors formed as films on the surface of the ceramic substrate and chip resistors may be connected to each other. However, in general, the capacitors formed as the films have a small capacitance value, and variations thereof are large. Therefore, when it is desired to increase a capacitance value of the composite electronic part 1, or when it is desired to enhance accuracy of the capacitance value, it is preferable to use the chip capacitors 3. Further, the composite electronic part may include other circuit elements, for example, inductor elements, chip parts of diodes or transistors, or elements formed as films on the surface of the ceramic substrate. Further, the composite electronic part may be composed by combining circuit elements of the same type, such as the chip resistors and the film-like resistor elements 2. Further, the composite electronic part may be a composite electronic part of a network circuit, in which all of the four common electrodes 8B shown in FIG. 1B are electrically connected to one another. Further, when the height difference between the film circuit elements and the chip-like electronic parts is 0.1 mm or more, the method of manufacturing a composite electronic part according to this embodiment is considered to be particularly advantageous.

The composite electronic part 1 according to this embodiment is a so-called ball grid array type electronic part, in which the conductive projections 6 are arrayed at the fixed intervals vertically and horizontally. Hence, electric capacitance capable of being accumulated between the conductive projections 6 and a reflection coefficient of the electricity can be calculated easily, and much of an influence of external noise can be removed. Hence, it is preferable to use the composite electronic part 1 for the purpose of avoiding the influence of the noise as much as possible, such as for a communication instrument.

In the composite electronic part 1 according to this embodiment, the difference between the maximum value and the minimum value of the distance from the flat surface 4A to the other substrate surface 5B becomes 100 μm or less. In order to further restrict the unevenness of the disposition amount of the cream solder 7C on the other substrate surface 5B, it is preferable that the difference between the maximum value and the minimum value of the distance from the flat surface 4A to the other substrate surface 5B be as small as possible, such as 50 μm or less, 30 μm or less, 20 μm or less, and further, 10 μm or less. Note that it is preferable to set the above-described difference to 2 μm or more in terms of the manufacturing efficiency. Further, considering the manufacturing efficiency, it is more preferable to set the difference to 5 μm or more, and it is extremely preferable to set the difference to 10 μm or more. If the flat surface 4A is flat, it becomes easy to suck the upper surface of the protective layer 4 when the composite electronic part 1 is mounted on the packaged board. Further, in the case of printing some display on the upper surface of the protective layer 4, the printing becomes easy. As means for forming the flat surface 4A, means may be employed, which supplies the resin paste 16 that becomes the protective layer 4 onto the one substrate surface 5A, cures the resin paste 16, and thereafter grinds the upper surface of the protective layer 4. In order to further enhance the flatness of the flat surface 4A, it is preferable to use, as the grinding means, the means as grinding using alumina powder and the like. Further, the upper surface of the protective layer 4 may be ground after the upper surface of the protective layer 4 is formed by using the frame 15.

In the manufacturing process of the composite electronic part 1 according to this embodiment, the large-scale insulating substrate 13 is divided by the dicing. Instead of dicing, a part or entirety of the large-scale insulating substrate 13 may be divided in such a manner that the linear dividing portions 14 are used as dividing grooves, and the large-scale insulating substrate 13 is bent in a direction of opening the dividing grooves. For example, a method may be employed, in which one of the longitudinal or lateral linear dividing portions 14 is divided by the dicing, and the other of those is divided by the method of bending the large-scale insulating substrate 13 in the direction of opening the dividing grooves. In the case of dividing the large-scale insulating substrate 13 by the dicing, it is possible to obtain favorable dimensional accuracy in the case of performing the division. Further, in this case, an impact applied to the large-scale insulating substrate 13 is small, and the conductive projections 6 or the chip capacitors 3 can be prevented from being peeled off from the large-scale insulating substrate 13. Further, in the case of dividing the large-scale insulating substrate 13 by the method of bending the large-scale insulating substrate 13 in the direction of opening the dividing grooves, cost involved in the division step can be suppressed to be low. In order to restrict the conductive projections 6 from being peeled off from the large-scale insulating substrate 13 owing to the impact application, it is preferable to perform the division step before the conductive material arrangement step of forming the conductive projections 6.

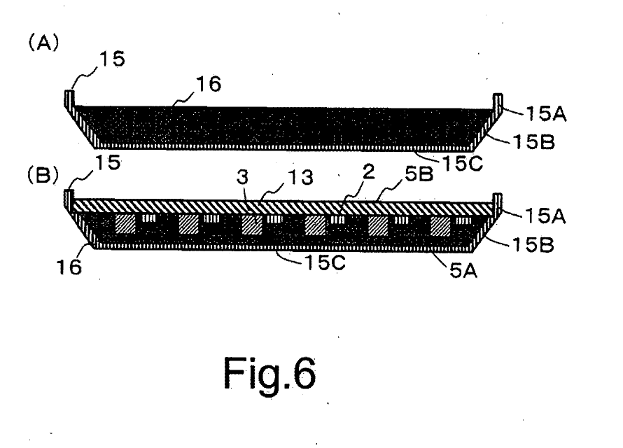

The resin filling step using the frame 15 in this embodiment, which is shown in FIGS. 5B and 5C, may be performed as shown in FIGS. 6A and 6B. Specifically, as shown in FIG. 6A, first, the epoxy resin paste 16 to be the protective layer 4 later is supplied to the inside of the frame 15 in a state where the opening 15A faces upwards. Then, as shown in FIG. 6B, the end surface of the large-scale ceramic substrate 13 is fitted to the opening 15A of the frame 15 so that the one substrate surface 5A of the large-scale ceramic substrate 13 for which the entire part arrangement step is ended comes into contact with the resin paste 16. Then, the space between the chip capacitors 3 and the resistor elements 2, and the like are filled with the resin paste 16 without any gap. The extra resin paste 16 that overflows from the inside of the frame 15 is removed. In the resin filling step using the frame 15, which is shown in FIGS. 6A and 6B, the resin paste 16 can be distributed sufficiently to the flat portion 15C without strongly deaerating the inside of the frame 15.

Further, the resin filling step using the frame 15 in this embodiment, which is shown in FIGS. 5B and 5C, can be replaced by a step to be described as below. Specifically, when the retaining member (not shown) that prevents the outflow of the resin paste 16 is disposed on the one substrate surface 5A and the resin paste 16 used has low viscosity, the resin paste 16 reserved by the retaining member may be left still at normal temperature for a predetermined time, without using the frame 15. Then, an upper surface of the resin paste 16 becomes flat, and after that, the resin paste 16 is cured by means such as heating. In this way, the flat surface 4A can be formed.

What is claimed is:

1. A method of manufacturing a composite electronic part, comprising the steps of:
arranging a film circuit element and a chip-like electronic part on one surface of a ceramic substrate;
disposing a protective layer for protecting the film circuit element and the chip-like electronic part on the one surface of the ceramic substrate, and flattening an upper surface of the protective layer; and
after both of the part arrangement step and the protective layer disposition step, arranging a plurality of conductive projections that become terminals of the film circuit element and the chip-like electronic part on another surface of the ceramic substrate in a state where the upper surface of the protective layer abuts on a horizontal plane.

2. A method of manufacturing a composite electronic part according to claim 1, wherein, when the upper surface of the protective layer is flattened in the protective layer disposition step, a difference between a maximum value and a minimum value of distances from the upper surface of the protective layer, the upper surface being exposed to a side opposite to a side that abuts on the one surface of the ceramic substrate, to the another surface of the ceramic substrate is set to 2 μm or more to 100 μm or less.

3. A method of manufacturing a composite electronic part according to claim 1, wherein, in the protective layer disposition step, the upper surface of the protective layer is flattened in such a manner that a resin paste that becomes the protective layer is cured so as to be parallel with a flat bottom surface of a frame, and a portion of the resin paste, parallel with the bottom surface, is defined as the upper surface of the protective layer.

4. A method of manufacturing a composite electronic part according to claim 1, wherein, in the protective layer disposition step, the upper surface of the protective layer is flattened in such a manner that a resin paste that becomes the protective layer is supplied onto the one surface, the resin paste is thereafter cured, and the upper surface of the protective layer is thereafter ground.

5. A method of manufacturing a composite electronic part according to claim 1, wherein:
the ceramic substrate has holes that extend from the one surface to the another surface, and an opening area of each of the holes on the one surface is made smaller than an opening area of each of the holes on the another surface;
the method of manufacturing a composite electronic part includes, a step of supplying a conductive paste from openings of the holes on the another surface, filling the holes with the conductive paste, and then solidifying the conductive paste, in any one or more stages of a step previous to the part arrangement step, the part arrangement step and the conductive material arrangement step; and
conduction of the film circuit element and the chip-like electronic part to the plurality of conductive projections is realized through the holes.

6. A method of manufacturing a composite electronic part, comprising the steps of:
arranging a film circuit element and a chip-like electronic part on one surface of a large-scale ceramic substrate that becomes a large number of unit ceramic substrates by being divided;
disposing a protective layer for protecting the film circuit element and the chip-like electronic part on the one surface of the large-scale ceramic substrate, and flattening an upper surface of the protective layer;
after both of the part arrangement step and the protective layer disposition step, arranging a plurality of conductive projections that become terminals of the film circuit element and the chip-like electronic part on another surface of the large-scale ceramic substrate in a state where the upper surface of the protective layer abuts on a horizontal plane; and
dividing the large-scale ceramic substrate together with the protective layer.

7. A method of manufacturing a composite electronic part according to claim 6, wherein, when the upper surface of the protective layer is flattened in the protective layer disposition step, a difference between a maximum value and a minimum value of distances from the upper surface of the protective layer, the upper surface being exposed to a side opposite to a side that abuts on the one surface of the large-scale ceramic substrate, to the another surface of the large-scale ceramic substrate is set to 2 μm or more to 100 μm or less.

8. A method of manufacturing a composite electronic part according to claim 6, wherein, in the protective layer disposition step, the upper surface of the protective layer is flattened in such a manner that a resin paste that becomes the protective layer is cured so as to be parallel with a flat bottom surface of a frame, and a portion of the resin paste, parallel with the bottom surface, is defined as the upper surface of the protective layer.

9. A method of manufacturing a composite electronic part according to claim 6, wherein, in the protective layer disposition step, the upper surface of the protective layer is flattened in such a manner that a resin paste that becomes the protective layer is supplied onto the one surface, the resin paste is thereafter cured, and the upper surface of the protective layer is thereafter ground.

10. A method of manufacturing a composite electronic part according to claim 6, wherein:
the large-scale ceramic substrate has holes that extend from the one surface to the another surface, and an opening area of each of the holes on the one surface is made smaller than an opening area of each of the holes on the another surface;
the method of manufacturing a composite electronic part includes, a step of supplying a conductive paste from openings of the holes on the another surface, filling the holes with the conductive paste, and then solidifying the conductive paste, in any one or more stages of a step previous to the part arrangement step, the part arrangement step and the conductive material arrangement step; and
conduction of the film circuit element and the chip-like electronic part to the plurality of conductive projections is realized through the holes.

11. A composite electronic part, comprising:
a ceramic substrate;
a film-circuit element;
a chip-like electronic part;
a protective layer for protecting the film circuit element and the chip-like electronic part, the protective layer being disposed on one surface of the ceramic substrate; and
a plurality of conductive projections that become terminals of the film circuit element and the chip-like electronic part, the conductive projections being arranged on another surface of the ceramic substrate,
wherein a difference between a maximum value and a minimum value of distances from an upper surface of the protective layer to the another surface of the ceramic substrate is 2 μm or more to 100 μm or less.

12. A composite electronic part according to claim 11, wherein a difference between a maximum distance and a minimum distance from vertexes of the plurality of conductive projections to the upper surface of the protective layer is 5 μm or more to 100 μm or less.

13. A composite electronic part according to claim 11, wherein the ceramic substrate has a plurality of holes that extend from the one surface to the another surface, an opening area of each of the holes on the one surface is smaller than an opening area of each of the holes on the another surface, and conduction of the film circuit element and the chip-like electronic part to the conductive projections is realized through a conductive substance filling the holes.
